(19) United States
(12) Patent Application Publication
(10) Pub. No.: US 2026/0211329 A1
(43) Pub. Date: Jul. 23, 2026

(54) SOLUBLE POLYMER COMPOUND, METHOD FOR PRODUCING SOLUBLE POLYMER COMPOUND, RESIN COMPOSITION, RESIN COMPOSITION FILM, CURED FILM, AND ELECTRONIC COMPONENT

(71) Applicant: Toray Industries, Inc., Tokyo (JP)

(72) Inventors: Keigo KATO, Otsu-shi, Shiga (JP); Kazuyuki MATSUMURA, Otsu-shi, Shiga (JP); Yoshiko TATEOKA, Otsu-shi, Shiga (JP)

(73) Assignee: Toray Industries, Inc., Tokyo (JP)

(21) Appl. No.: 19/131,111

(22) PCT Filed: Dec. 20, 2023
(86) PCT No.: PCT/JP2023/045659

§ 371 Date: May 19, 2025

(30) Foreign Application Priority Data
Jan. 23, 2023 (JP) 2023-007806

(51) Int. Cl. G03F 7/075; C08G 73/10

(52) U.S. Cl. CPC G03F 7/0757; C08G 73/1067

(57) ABSTRACT

Provided is a soluble polymer compound containing a structure having a repeating unit represented by chemical formula (1) and further containing a structure derived from an acid anhydride silane residue:

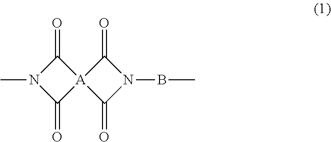

### TECHNICAL FIELD OF THE INVENTION

The present invention relates to a soluble polymer compound, a method for producing the soluble polymer compound, a resin composition, a resin composition film, a cured film, and an electronic component. More specifically, the present invention relates to a soluble polymer compound which is suitable for use in surface protection films for semiconductor elements and electronic components, interlayer insulating films, and structures for MEMS (microelectromechanical systems).

### BACKGROUND ART OF THE INVENTION

Conventionally, polyimide-based materials and polybenzoxazole-based materials, which have excellent heat resistance, electrical insulation, and mechanical properties, have been widely used for surface protection films and interlayer insulating films of semiconductor elements. In recent years, accompanying the demand for higher density and higher performance of semiconductor elements, photosensitive materials are required for the surface protection films and interlayer insulating films from the viewpoint of production efficiency. Furthermore, photosensitive materials are required to be processed with high aspect ratios for various packaging structures of recent semiconductor elements and MEMS. In order to meet such demands, polyimide-based photo cationic polymerization materials intended to improve mechanical properties and thermal properties have been disclosed (for example, Patent document 1).

On the other hand, as a practical subject matter, surface protection films and interlayer insulating films are required to have sufficient adhesion with various substrates. In response to such a requirement, an alkoxysilane-modified polyamide acid solution material capable of forming a thick film without peeling from the substrate (for example, Patent document 2) and a silane coupling agent having an amide acid structure useful for adhesion between organic materials and metal materials (for example, Patent document 3) have been disclosed.

### PRIOR ART DOCUMENTS

### Patent Documents

Patent document 1: WO 2021/059843
Patent document 2: JP-A-2019-7020
Patent document 3: JP-A-2015-137271

### SUMMARY OF THE INVENTION

### Problems to be Solved by the Invention

However, even if the above-described photo cationic polymerization material is combined with an alkoxy-modified polyamide acid or a silane coupling agent having an amide acid structure as described above in Patent document 2 or 3, although an adhesion force with a substrate as a cured coating film is exhibited, it is difficult to satisfy the storage stability and fine pattern processability requirements of the material.

In view of such circumstances, as the result of the present inventors' earnest study, it has been found that the specific soluble polymer compound of the present invention exhibits sufficient adhesion, storage stability and fine pattern processability.

Accordingly, an object of the present invention is to provide a soluble polymer compound capable of exhibiting sufficient adhesion, storage stability, and fine pattern processability, a method for producing the soluble polymer compound, a resin composition containing the soluble polymer compound, a resin composition film comprising the resin composition, a cured film obtained by curing the resin composition or the resin composition film, and an electronic component having the cured film.

### Means for Solving the Problems

To achieve the above-described objects, the present invention has the following configurations.

<1> A soluble polymer compound containing a structure having a repeating unit represented by chemical formula (1) and further containing a structure derived from an acid anhydride silane residue, wherein the soluble polymer compound (hereinafter referred to as “(a) soluble polymer compound”) contains a structure represented by chemical formula (2), and in the chemical formula (2), the acid anhydride silane residue is derived from a structure represented by chemical formula (4).

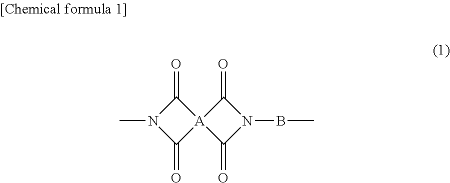

In chemical formula (1), A represents a tetravalent tetracarboxylic acid residue having two or more carbon atoms, and B represents a divalent diamine residue having two or more carbon atoms.

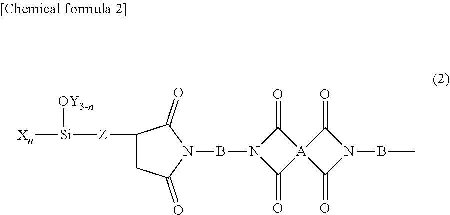

In chemical formula (2), A represents a tetravalent tetracarboxylic acid residue having 2 or more carbon atoms, B represents a divalent diamine residue having 2 or more carbon atoms, and n represents an integer of 0 to 3. X represents a structure represented by chemical formula (3), and an oxygen atom in chemical formula (3) is bonded to a Si atom in chemical formula (2). Y represents a hydrocarbon group having 1 to 10 carbon atoms, and Z represents a silane residue having 1 to 10 carbon atoms.

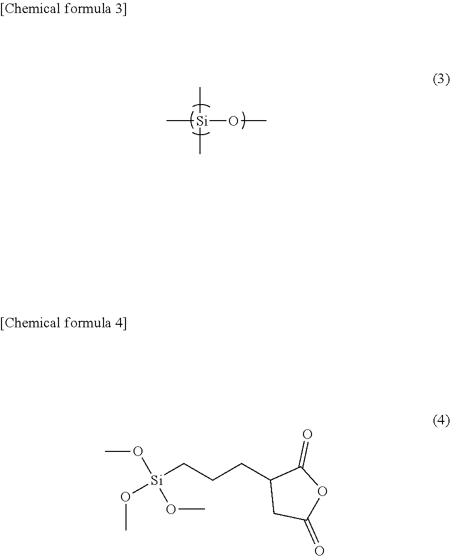

<2> The soluble polymer compound according to <1>, wherein the tetracarboxylic acid residue of the formula (1) has a structure derived from an alicyclic tetracarboxylic dianhydride.

<3> A method for producing the soluble polymer compound (a) according to <1>, comprising the step of copolymerizing raw materials used in a polymerization process at a condition where the following equation (1) is satisfied when referring a total amount of tetracarboxylic dianhydrides to as A mol, a total amount of diamines to as B mol, and a total amount of acid anhydride silanes to as C mol.

$$0.6 ≦ B / ( A + 0.5 C ) ≦ 0.98 \qquad Equation ( 1 )$$

<4> A resin composition containing the soluble polymer compound (a) according to <1>.

<5> A negative-type photosensitive resin composition further containing (b) a polymerizable compound and (c) a photopolymerization initiator in the resin composition according to <4>.

<6> The negative-type photosensitive resin composition according to <5>, wherein the (b) polymerizable compound is a cationic polymerizable compound, and the (c) photopolymerization initiator is a photo cationic polymerization initiator.

<7> A resin composition film comprising the resin composition according to <4>.

<8> A cured film obtained by curing the resin composition according to <4> or the resin composition film according to <7>.

<9> An electronic component comprising the cured film according to <8>.

### Effect According to the Invention

According to the present invention, can be provided a soluble polymer compound capable of exhibiting sufficient adhesion, storage stability, and fine pattern processability, a method for producing the soluble polymer compound, a resin composition containing the soluble polymer compound, a resin composition film comprising the resin composition, a cured film obtained by curing the resin composition or the resin composition film, and an electronic component having the cured film.

### EMBODIMENTS FOR CARRYING OUT THE INVENTION

Hereinafter, the present invention will be explained in detail together with embodiments.

The present invention relates to a soluble polymer compound containing a structure having a repeating unit represented by chemical formula (1) and further containing a structure derived from an acid anhydride silane residue, wherein the soluble polymer compound (hereinafter referred to as “(a) soluble polymer compound”) contains a structure represented by chemical formula (2), and in the chemical formula (2), the acid anhydride silane residue is derived from a structure represented by chemical formula (4).

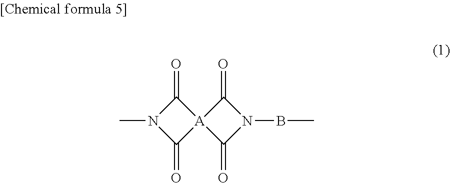

In chemical formula (1), A represents a tetravalent tetracarboxylic acid residue having two or more carbon atoms, and B represents a divalent diamine residue having two or more carbon atoms.

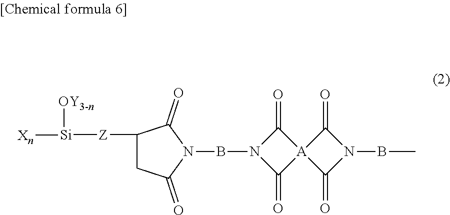

In chemical formula (2), A represents a tetravalent tetracarboxylic acid residue having 2 or more carbon atoms, B represents a divalent diamine residue having 2 or more carbon atoms, and n represents an integer of 0 to 3. X represents a structure represented by chemical formula (3), and an oxygen atom in chemical formula (3) is bonded to a Si atom in chemical formula (2). Y represents a hydrocarbon group having 1 to 10 carbon atoms, and Z represents a silane residue having 1 to 10 carbon atoms.

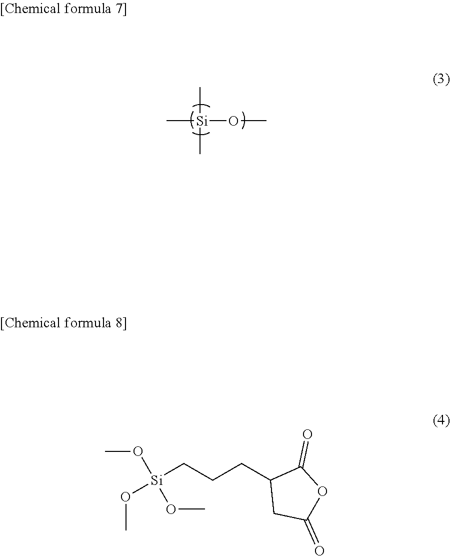

The soluble polymer compound of the present invention contains a structure having a repeating unit represented by chemical formula (1). By containing a structure having a repeating unit represented by chemical formula (1), the composition has excellent storage stability when made into a composition, and the mechanical strength of the cured film thereof is excellent.

The weight average molecular weight of the soluble polymer compound of the present invention is not particularly limited, but it is preferable that the weight average molecular weight is 1,000 or more and 200,000 or less. The soluble polymer compound may be used alone or in combination of two or more kinds. The weight average molecular weight of the soluble polymer compound in the present invention is determined by gel permeation chromatography (GPC) and calculated in terms of polystyrene.

The term “soluble” in the soluble polymer compound indicates a polymer compound that dissolves in an amount of 0.1 g or more in 100 g of γ-butyrolactone solution at 25° C.

The soluble polymer compound of the present invention is preferably alkali soluble. If it is alkali soluble, it is preferable because it can be developed with an alkaline aqueous solution without using an organic solvent that is a factor of environmental load during development at the time of pattern processing. The “alkali soluble” referred to here indicates means one that dissolves at 0.1 g or more in 100 g of a 2.38 mass % aqueous solution of tetramethyl ammonium hydroxide at 25° C.

In order to exhibit alkali solubility, it is preferred that the soluble polymer compound of the present invention has an alkali soluble functional group. The alkali soluble functional group is a functional group having acidity, and specifically exemplified are a phenolic hydroxyl group, a carboxyl group, a sulfonic acid group, etc. Among the above-described alkali soluble functional groups, it is preferable that the alkali soluble functional group is a phenolic hydroxyl group from the viewpoint of storage stability of the resin composition and corrosion of copper wiring which is a conductive material. In particular, it is preferable that the soluble polymer compound of the present invention is a compound having a phenolic hydroxyl group in the molecular chain.

The soluble polymer compound of the present invention contains a structure derived from an acid anhydride silane residue. The acid anhydride silane indicates a silane compound having at least one acid anhydride group. By containing a structure derived from an acid anhydride silane residue, the adhesion of the soluble polymer compound is improved. Moreover, as compared with the case where a silane compound such as a silane coupling agent is simply added to the soluble polymer compound, the soluble polymer compound of the present invention exhibits a good storage stability.

When the soluble polymer compound of the present invention is referred to as (a) soluble polymer compound, the (a) soluble polymer compound contains a structure represented by chemical formula (2). By containing the structure represented by chemical formula (2), the (a) soluble polymer compound exhibits good adhesion and storage stability.

Furthermore, in the (a) soluble polymer compound, the acid anhydride silane residue in the above-described chemical formula (2) is derived from a structure represented by chemical formula (4). By satisfying the above, adhesion and storage stability are improved.

As an example of the acid anhydride silane represented by the chemical formula (4), X-12-967C (trade name, supplied by Shin-Etsu Chemical Co., Ltd.) can be exemplified.

Although the soluble polymer compound of the present invention is preferably a polyimide or polyamideimide, from the viewpoint of alkali solubility, it is more preferably a compound having at least one or more structures selected from the structures represented by the following chemical formulas (5) and (6).

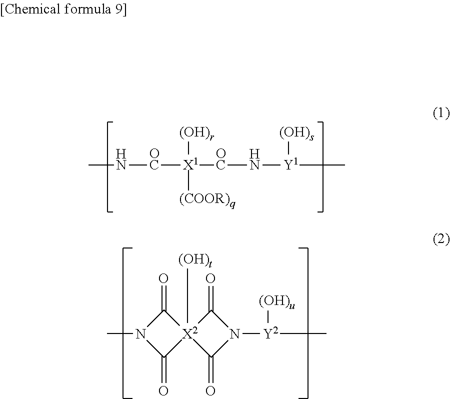

In chemical formulas (5) and (6), X¹ represents a divalent to decavalent organic group, X² represents a tetravalent to decavalent organic group, Y¹ and Y² each independently represents a divalent to tetravalent organic group, R represents a hydrogen atom or an organic group having 1 to 20 carbon atoms, q represents an integer of 0 to 2, and r, s, t, and u each independently represents an integer of 0 to 4.

In the chemical formulas (5) and (6), Y¹ and Y² each independently represents a divalent to tetravalent organic group, and represents an organic group derived from a diamine.

B in the chemical formulas (1) and (2) and Y¹ and Y² in the chemical formulas (5) and (6) of the soluble polymer compound preferably contain a diamine residue having a phenolic hydroxyl group. By containing a diamine residue having a phenolic hydroxyl group, because an appropriate solubility of resin in an alkaline developer can be obtained, a high contrast between exposed and unexposed areas can be obtained, and a desired pattern can be formed.

As specific examples of diamines having a phenolic hydroxyl group, for example, can be exemplified by aromatic diamines such as bis(3-amino-4-hydroxyphenyl) hexafluoro propane, bis(3-amino-4-hydroxyphenyl) sulfone, bis(3-amino-4-hydroxyphenyl) propane, bis(3-amino-4-hydroxyphenyl)methylene, bis(3-amino-4-hydroxyphenyl) ether, bis(3-amino-4-hydroxy) biphenyl, 2,2′-ditrifluoromethyl-5,5′-dihydroxyl-4,4′-diaminobiphenyl, bis(3-amino-4-hydroxyphenyl) fluorene, and 2,2′-bis(trifluoromethyl)-5,5′-dihydroxybenzidine; compounds in which a part of the hydrogen atoms of these aromatic rings or hydrocarbons is substituted with an alkyl group or fluoroalkyl group having 1 to 10 carbon atoms, a halogen atom, or the like; and diamines having the structures shown in the following Chemical Formula 10 and Chemical Formula 11, but are not limited thereto. The other diamines to be copolymerized may be used as they are or as the corresponding diisocyanate compounds or trimethyl silylated diamines. Further, two or more of these diamine components may also be used in combination.

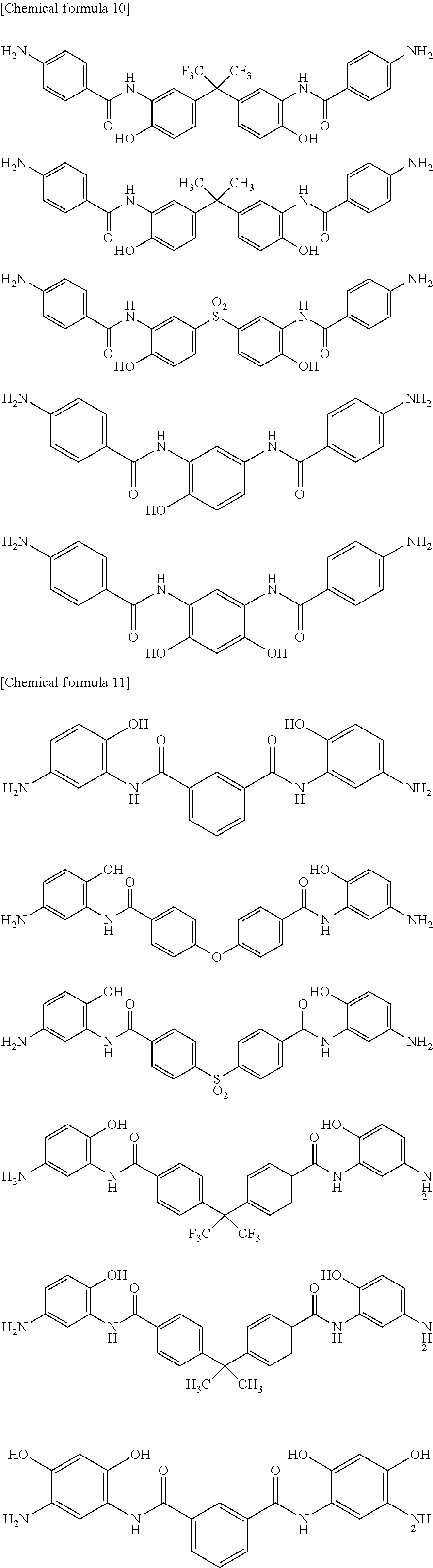

B in the chemical formulas (1) and (2), and Y¹ and Y² in the chemical formulas (7) and (8), may contain a diamine residue having an aromatic group other than those described above. By copolymerizing these, the heat resistance can be improved. As specific examples of diamine residues having an aromatic group can be exemplified by aromatic diamines such as 3,4′-diaminodiphenyl ether, 4,4′-diaminodiphenyl ether, 3,4′-diaminodiphenyl methane, 4,4′-diaminodiphenyl methane, 3,4′-diaminodiphenyl sulfone, 4,4′-diaminodiphenyl sulfone, 3,4′-diaminodiphenyl sulfide, 4,4′-diaminodiphenyl sulfide, 1,4-bis(4-aminophenoxy)benzene, benzine, m-phenylenediamine, p-phenylenediamine, 1,5-naphthalenediamine, 2,6-naphthalenediamine, bis(4-aminophenoxyphenyl) sulfone, bis(3-aminophenoxyphenyl) sulfone, bis(4-aminophenoxy) biphenyl, bis {4-(4-aminophenoxy)phenyl}ether, 1,4-bis(4-aminophenoxy)benzene, 2,2′-dimethyl-4,4′-diaminobiphenyl, 2,2′-diethyl-4,4′-diaminobiphenyl, 3,3′-dimethyl-4,4′-diaminobiphenyl, 3,3′-diethyl-4,4′-diaminobiphenyl, 2,2′,3,3′-tetramethyl-4,4′-diaminobiphenyl, 3,3′,4,4′-tetramethyl-4,4′-diaminobiphenyl, and 2,2′-bis(trifluoromethyl)-4,4′-diaminobiphenyl, and compounds in which a part of the hydrogen atoms of these aromatic rings or hydrocarbons is substituted with an alkyl group or fluoroalkyl group having 1 to 10 carbon atoms, a halogen atom, or the like, but are not limited thereto. The other diamines to be copolymerized can be used as they are or as the corresponding diisocyanate compounds or trimethyl silylated diamines. Two or more of these diamine components may be used in combination.

X¹ and X² in the above-described chemical formulas (5) and (6) are preferably carboxylic acid residues, X¹ is a divalent to decavalent organic group, and X² is a tetravalent to decavalent organic group.

The carboxylic acid residue preferably has a structure derived from an alicyclic tetracarboxylic dianhydride, namely, it is preferred that the soluble polymer compound is at least one compound selected from the group consisting of polyimide and polyamideimide, and further has a structure derived from an alicyclic tetracarboxylic dianhydride.

By the carboxylic acid residue having a structure derived from an alicyclic tetracarboxylic dianhydride, the light transmittance of the resin composition at the exposure wavelength increases, and the processing using a thick film of 20 μm or more is facilitated. Furthermore, although the reason is unclear, by the soluble polymer compound having a structure derived from an alicyclic tetracarboxylic dianhydride, the reactivity of cationic polymerization is enhanced as compared with an aromatic acid dianhydrides, and it is preferred in the point that the chemical resistance of the film is improved when the resin composition is made into a cured film.

Among the alicyclic tetracarboxylic dianhydrides, alicyclic tetracarboxylic dianhydrides having a polycyclic structure are preferred because they improve the chemical resistance and ion migration resistance when made into a cured material.

In cases where the soluble polymer compound in the present invention has a structure derived from an alicyclic tetracarboxylic dianhydride having a polycyclic structure, it is preferred that the soluble polymer compound has a structure derived from a compound represented by at least one of the following chemical formulas (7) or (8).

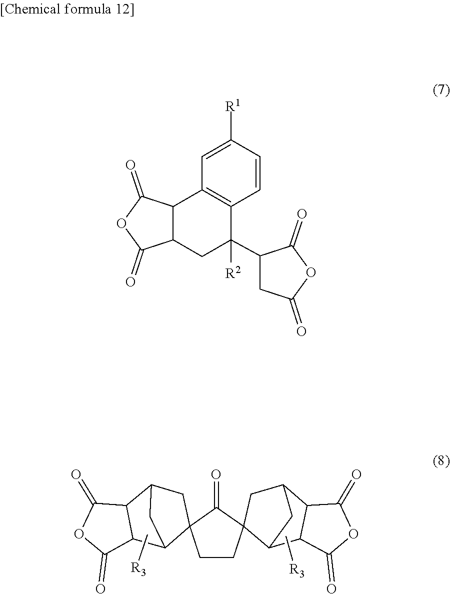

In the formula, R¹, R² and R³ each independently represents a hydrogen atom or a methyl group.

By the soluble polymer compound having a structure derived from a compound represented by chemical formula (7) or (8), since the resin skeleton has a flexibility, as a resin composition before curing, it has a high solubility in organic solvents, is unlikely to cause resin precipitation in the resin composition, and is preferable in terms of excellent storage stability.

Further, for the same reasons as above, the tetracarboxylic acid residue represented by A in the chemical formulas (1) and (2) is also preferably an alicyclic tetracarboxylic dianhydride, more preferably an alicyclic tetracarboxylic dianhydride having a polycyclic structure, and further preferably has a structure derived from a compound represented by at least one of chemical formulas (7) and (8).

As specific examples of organic groups derived from alicyclic tetracarboxylic dianhydrides having a polycyclic structure, exemplified are 4-(2,5-dioxotetrahydrofuran-3-yl)-1,2,3,4-tetrahydronaphthalene-1,2-dicarboxylic dianhydride, 4-(2,5-dioxotetrahydrofuran-3-yl)-4-methyl-1,2,3,4-tetrahydronaphthalene-1,2-dicarboxylic dianhydride, 4-(2,5-dioxotetrahydrofuran-3-yl)-7-methyl-1,2,3,4-tetrahydronaphthalene-1,2-dicarboxylic dianhydride, norbornane-2-spiro-2′-cyclopentanone-5′-spiro-2″-norbornane-5,5″,6,6″-tetracarboxylic dianhydride, and norbornane-2-spiro-2′-cyclohexanone-6′-spiro-2″-norbornane-5,5″,6,6″-tetracarboxylic dianhydride.

The above-described carboxylic acid residue or tetracarboxylic dianhydride may contain an acid dianhydride other than the alicyclic tetracarboxylic dianhydride having a polycyclic structure. Specifically, exemplified are aromatic tetracarboxylic dianhydrides such as pyromellitic dianhydride, 3,3′,4,4′-biphenyl tetracarboxylic dianhydride, 2,3,3′,4′-biphenyl tetracarboxylic dianhydride, 2,2′,3,3′-biphenyl tetracarboxylic dianhydride, 3,3′,4,4′-benzophenone tetracarboxylic dianhydride, 2,2′,3,3′-benzophenone tetracarboxylic dianhydride, 2,2-bis(3,4-dicarboxyphenyl) propane dianhydride, 2,2-bis(2,3-dicarboxyphenyl) propane dianhydride, 1,1-bis(3,4-dicarboxyphenyl) ethane dianhydride, 1,1-bis(2,3-dicarboxyphenyl) ethane dianhydride, bis(3,4-dicarboxyphenyl) methane dianhydride, bis(2,3-dicarboxyphenyl) methane dianhydride, bis(3,4-dicarboxyphenyl) sulfone dianhydride, bis(3,4-dicarboxyphenyl) ether dianhydride, 1,2,5,6-naphthalene tetracarboxylic dianhydride, 9,9-bis(3,4-dicarboxyphenyl) fluorene dianhydride, 9,9-bis {4-(3,4-dicarboxyphenoxy)phenyl}fluorene dianhydride, 2,3,6,7-naphthalene tetracarboxylic dianhydride, 2,3,5,6-pyridine tetracarboxylic dianhydride, 3,4,9,10-perylene tetracarboxylic dianhydride, and 2,2-bis(3,4-dicarboxyphenyl) hexafluoro propane dianhydride; 3,3′,4,4′-diphenylsulfone tetracarboxylic dianhydride, 1,2,3,4-cyclobutane tetracarboxylic dianhydride, 1,2,3,4-cyclopentane tetracarboxylic dianhydride, 1,2,4,5-cyclohexane tetracarboxylic dianhydride, 5-(2,5-dioxotetrahydrofuryl)-3-methyl-3-cyclohexene-1,2-dicarboxylic dianhydride, 2,3,5-tricarboxy-2-cyclopentane acetic dianhydride, 2,3,4,5-tetrahydrofuran tetracarboxylic dianhydride, and the like, but are not limited thereto. Further, these may be used alone or in combination of two or more.

Further, the molecular chain terminals of the soluble polymer compound of the present invention may be blocked with a terminal blocking agent of a carboxylic acid or an acid anhydride having a hydroxyl group, a carboxyl group, a sulfonic acid group, a thiol group, a vinyl group, an ethynyl group, or an allyl group. By satisfying the above, the dissolution rate of the soluble polymer compound in an alkaline aqueous solution and the mechanical properties of the resulting cured film can be easily controlled to a preferred range. Furthermore, a plurality of terminal blocking agents may be reacted to introduce a plurality of different terminal groups.

As the terminal blocking agent, it is preferred to use an acid anhydride, a monocarboxylic acid, a monoacid chloride compound, or a mono active ester compound. By using these as the terminal blocking agent, the molecular chain terminal of the soluble polymer compound becomes an acid anhydride residue, and when the soluble polymer compound is applied to a cationic polymerization type photosensitive resin composition, the cationic polymerization reaction is easily promoted, which is preferable in that the chemical resistance of the cured film is improved.

As the acid anhydrides, monocarboxylic acids, monoacid chloride compounds, and mono active ester compounds as the terminal blocking agents, preferred are acid anhydrides such as phthalic anhydride, maleic anhydride, nadic anhydride, cyclohexane dicarboxylic anhydride, and 3-hydroxyphthalic anhydride; monocarboxylic acids such as 3-carboxyphenol, 4-carboxyphenol, 3-carboxythiophenol, 4-carboxythiophenol, 1-hydroxy-7-carboxynaphthalene, 1-hydroxy-6-carboxynaphthalene, 1-hydroxy-5-carboxynaphthalene, 1-mercapto-7-carboxynaphthalene, 1-mercapto-6-carboxynaphthalene, 1-mercapto-5-carboxynaphthalene, 3-carboxybenzenesulfonic acid and 4-carboxybenzenesulfonic acid, and monoacid chloride compounds in which the carboxyl groups of these are turned into acid chlorides; monoacid chloride compounds in which only one carboxyl group of dicarboxylic acids such as terephthalic acid, phthalic acid, maleic acid, cyclohexane dicarboxylic acid, 1,5-dicarboxynaphthalene, 1,6-dicarboxynaphthalene, 1,7-dicarboxynaphthalene, and 2,6-dicarboxynaphthalene is turned into acid chloride; active ester compounds obtained by reacting a monoacid chloride compound with N-hydroxy benzotriazole, imidazole, or N-hydroxy-5-norbornene-2,3-dicarboxyimide; and the like. Two or more of these may be used.

The soluble polymer compound of the present invention can be synthesized, for example, by a production method including the following steps 1 and 2, but is not limited thereto.

Step 1: A step of reacting tetracarboxylic dianhydride, diamine, and at least one of amino silane and acid anhydride silane in a solvent at a low temperature to prepare a polyimide precursor.

Step 2: A step of reacting the polyimide precursor at a high temperature to prepare a polyimide.

Regarding step 1, the tetracarboxylic dianhydride, diamine, and amino silane or acid anhydride silane may be, for example, those described above. Further, the synthesis may be performed by replacing a part of the tetracarboxylic dianhydride and diamine with the terminal blocking agent.

As the solvent used in step 1, it is preferred to use a polar solvent from the viewpoint of solubility, and for example, it is preferred to use dimethylacetamide, N-methyl pyrrolidone, γ-butyrolactone, or the like.

The reaction temperature in step 1 is preferably a low temperature of 140° C. or lower from the viewpoint of being capable of improving the reactivity, and is preferably 60° C. or higher from the viewpoint of the solubility of tetracarboxylic dianhydride, diamine, and amino silane or acid anhydride silane.

Regarding step 2, the reaction temperature is preferably a high temperature of 160° C. or higher in order to sufficiently imidize the polyimide precursor synthesized in step 1, and is preferably 220° C. or lower in consideration of the boiling point of the aforementioned solvent.

Further, as the production method of the soluble polymer compound of the present invention, except the above-described method including steps 1 and 2, known methods for synthesizing polyimides can be used. For example, as methods for obtaining a polyimide precursor can be employed a method of reacting tetracarboxylic dianhydride with a dicarboxylic anhydride and a diamine compound at a low temperature, a method of obtaining a diester from tetracarboxylic dianhydride and an alcohol, and then reacting the diamine and monoamine in the presence of a condensing agent, etc. Thereafter, a polyimide can be synthesized using a known imidization reaction. When obtaining a polyimide using these methods, the soluble polymer compound of the present invention can be obtained by adding at least one of amino silane and acid anhydride silane in any of the steps, but it is preferable to add it in the step of preparing the above-described polyimide precursor.

Furthermore, in the production method of (a) soluble polymer compound, it is preferred that raw materials used in a polymerization process are copolymerized at a condition satisfying the following equation (1) when referring a total amount of tetracarboxylic dianhydrides to as A mol, a total amount of diamines to as B mol, and a total amount of acid anhydride silanes to as C mol.

$$0.6 ≦ B / ( A + 0.5 C ) ≦ 0.98 \qquad Equation ( 1 )$$

Regarding the above-described equation (1), by satisfying 0.6≤B/(A+0.5 C), the weight average molecular weight of the polymer compound easily becomes 1,000 or more, which is preferable in terms of film formability and storage stability when the resin composition is made into a film. In addition, by satisfying (A+0.5 C)≤0.98, the proportion of the polymer compound having an amine residue at the end is reduced, and when the soluble polymer compound (a) is applied to a cationic polymerization type photosensitive resin composition, the cationic polymerization reaction is easily progressed, which is preferable in terms of improving chemical resistance and pattern processability when the resin composition is made into a cured film.

In the present invention, it is preferred that the (a) soluble polymer compound is polymerized by the above-described method, then charged into a large amount of water or a mixture of methanol and water, precipitated, filtered, dried, and isolated. The drying temperature is preferably 40 to 100° C., more preferably 50 to 80° C. By this operation, unreacted monomers and oligomer components such as dimers and trimers are removed, and the film properties after heat curing can be improved.

The imidization ratio in the present invention can be easily determined, for example, by the following method. First, the infrared absorption spectrum of the polymer is measured to confirm the presence of absorption peaks (near 1780 cm-1 and near 1377 cm-1) of the imide structure originating from polyimide. Next, the infrared absorption spectrum of the polymer is measured using a sample having an imidization ratio of 100% after heat treatment at 350° C. for 1 hour, and the content of imide groups in the resin before heat treatment is calculated by comparing the peak intensities near 1377 cm-1 of the resin before and after heat treatment to determine the imidization ratio. Because the change in the ring closure ratio during thermal curing is suppressed and the effect of reducing stress is obtained, the imidization ratio is preferably 50% or more, and more preferably 80% or more.

If the soluble polymer compound of the present invention is referred to as (a) a soluble polymer compound, the resin composition of the present invention contains (a) a soluble polymer compound. By containing (a) a soluble polymer compound, the resin composition of the present invention exhibits sufficient adhesion to a substrate and storage stability.

Furthermore, the resin composition of the present invention is preferably a negative-type photosensitive resin composition characterized by containing (b) a polymerizable compound and (c) a photopolymerization initiator. By containing (b) a polymerizable compound and (c) a photopolymerization initiator, the resin composition becomes a negative-type photosensitive resin composition which exhibits a pattern processability, in addition to sufficient adhesion to the substrate and storage stability.

The (b) polymerizable compound preferably contains at least one of a radical polymerizable compound or a cationic polymerizable compound, and the (c) photopolymerization initiator preferably contains at least one of a photo radical polymerization initiator or a photo cationic polymerization initiator. In particular, from the viewpoint of improving the resolution during pattern processing, it is more preferable that the (b) polymerizable compound contains a cationic polymerizable compound, and the (c) photopolymerization initiator contains a photo cationic polymerization initiator.

The radical polymerizable compound is a compound having a radical polymerizable group, and is a compound that reacts with radicals generated by irradiation with light such as ultraviolet light in the presence of a photo radical polymerization initiator. As the radical polymerizable group which the radical polymerizable compound has, exemplified are unsaturated double bond functional groups such as vinyl groups, allyl groups, acryloyl groups, and methacryloyl groups, and/or unsaturated triple bond functional groups such as propargyl groups, and among these, conjugated vinyl groups, acryloyl groups, and methacryloyl groups are preferred in terms of polymerizability.

As the radical polymerizable compounds, for example, exemplified are diethylene glycol diacrylate, triethylene glycol diacrylate, tetraethylene glycol diacrylate, diethylene glycol dimethacrylate, triethylene glycol dimethacrylate, tetraethylene glycol dimethacrylate, trimethylolpropane diacrylate, trimethylolpropane triacrylate, trimethylolpropane dimethacrylate, trimethylolpropane trimethacrylate, styrene, α-methyl styrene, 1,2-dihydro naphthalene, 1,3-diisopropenyl benzene, 3-methyl styrene, 4-methyl styrene, 2-vinyl naphthalene, butyl acrylate, butyl methacrylate, isobutyl acrylate, hexyl acrylate, isooctyl acrylate, isobornyl acrylate, isobornyl methacrylate, cyclohexyl methacrylate, 1,3-butanediol diacrylate, 1,3-butanediol dimethacrylate, neopentyl glycol diacrylate, 1,4-butanediol diacrylate, 1,4-butanediol dimethacrylate, 1,6-hexanediol diacrylate, 1,6-hexanediol dimethacrylate, 1,9-nonanediol dimethacrylate, 1,10-decanediol dimethacrylate, dimethylol-tricyclodecane diacrylate, pentaerythritol triacrylate, pentaerythritol tetraacrylate, pentaerythritol trimethacrylate, pentaerythritol tetramethacrylate, dipentaerythritol hexaacrylate, dipentaerythritol hexamethacrylate, 2-hydroxyethyl acrylate, 2-hydroxyethyl methacrylate, 1,3-diacryloyloxy-2-hydroxypropane, 1,3-dimethacryloyloxy-2-hydroxypropane, methylenebisacrylamide, N,N-dimethylacrylamide, N-methylolacrylamide, 2,2,6,6-tetramethyl piperidinyl methacrylate, 2,2,6,6-tetramethyl piperidinyl acrylate, N-methyl-2,2,6,6-tetramethyl piperidinyl methacrylate, N-methyl-2,2,6,6-tetramethylpiperidinyl acrylate, ethylene oxide-modified bisphenol A diacrylate, ethylene oxide-modified bisphenol A dimethacrylate, propylene oxide-modified bisphenol A diacrylate, propylene oxide-modified bisphenol A methacrylate, propoxylated ethoxylated bisphenol A diacrylate, propoxylated ethoxylated bisphenol A dimethacrylate, N-vinylpyrrolidone, and N-vinylcaprolactam, etc. These may be used alone or in combination of two or more.

The photoradical polymerization initiator is a compound that generates radicals when irradiated with an ultraviolet ray or the like. As the photoradical polymerization initiators, for example, exemplified are benzophenones such as benzophenone, Michler's ketone, 4,4-bis(diethylamino)benzophenone, and 3,3,4,4-tetra(t-butyl peroxycarbonyl)benzophenone; benzylidenes such as 3,5-bis(diethylamino benzylidene)-N-methyl-4-piperidone and 3,5-bis(diethylamino benzylidene)-N-ethyl-4-piperidone; coumarins such as 7-diethylamino-3-nonylcoumarin, 4,6-dimethyl-3-ethylamino coumarin, 3,3-carbonylbis(7-diethylamino coumarin), 7-diethylamino-3-(1-methylmethylbenzimidazolyl) coumarin, and 3-(2-benzothiazolyl)-7-diethylamino coumarin; anthraquinones such as 2-t-butylanthraquinone, 2-ethylanthraquinone, and 1,2-benzanthraquinone; benzoins such as benzoin methyl ether, benzoin ethyl ether, and benzoin isopropyl ether; thioxanthones such as 2,4-dimethylthioxanthone, 2,4-diethylthioxanthone, 2,4-diisopropylthioxanthone, and 2-isopropylthioxanthone; mercaptos such as ethylene glycol di(3-mercaptopropionate), 2-mercaptobenzthiazole, 2-mercaptobenzoxazole, and 2-mercaptobenzimidazole; glycines such as N-phenylglycine, N-methyl-N-phenylglycine, N-ethyl-N-(p-chlorophenyl)glycine, and N-(4-cyanophenyl)glycine; oximes such as 1-phenyl-1,2-butanedione-2-(o-methoxycarbonyl)oxime, 1-phenyl-1,2-propanedione-2-(o-methoxycarbonyl)oxime, 1-phenyl-1,2-propanedione-2-(o-ethoxycarbonyl)oxime, 1-phenyl-1,2-propanedione-2-(o-benzoyl)oxime, bis(α-isonitrosopropiophenone oxime)isophthal, 1,2-octanedione-1-[4-(phenylthio)phenyl]-2-(o-benzoyloxime), ethanone, 1-[9-ethyl-6-(2-methylbenzoyl)-9H-carbazolyl-3-il]-, and 1-(o-acetyloxime); benzyl dimethyl ketals such as 2,2-dimethoxy-1,2-diphenylethan-1-one; α-hydroxyalkylphenone such as 1-hydroxycyclohexyl phenyl ketone, 2-hydroxy-2-methyl-1-phenyl-propan-1-one, 1-[4-(2-hydroxyethoxy)-phenyl]-2-hydroxy-2-methyl-1-propan-1-one, and 2-hydroxy-1-{4-[4-(2-hydroxy-2-methyl-propionyl)-benzyl]phenyl}-2-methyl-propan-1-one; α-aminoalkylphenones such as 2-benzyl-2-dimethylamino-1-(4-morpholinophenyl)-butan-1-one, 2-methyl-1-[4-(methylthio)phenyl]-2-morpholinopropan-1-one, and 2-(dimethylamino)-2-[(4-methylphenyl)methyl]-1-[4-(4-morpholinyl)phenyl]-1-butanone; acylphosphine oxides such as 2,4,6-trimethylbenzoyldiphenyl-phosphine oxide, and bis(2,4,6-trimethylbenzoyl)-phenylphosphine oxide; 2,2′-bis(o-chlorophenyl)-4,4′,5,5′-tetraphenylbiimidazole; etc.

A cationic polymerizable compound is a compound having a cationic polymerizable group, and it reacts with cations generated by irradiation with light such as ultraviolet ray in the presence of a cationic polymerization initiator. As the cationic polymerizable compounds, exemplified are cyclic ether compounds (epoxy compounds, oxetane compounds, etc.), ethylenic unsaturated compounds (vinyl ethers, styrenes, etc.), bicycloorthoesters, spiroorthocarbonates, spiroorthoesters, and the like.

As the epoxy compounds, known compounds can be used, including aromatic epoxy compounds, alicyclic epoxy compounds and aliphatic epoxy compounds.

As the aromatic epoxy compounds, exemplified are glycidyl ethers of mono- or polyhydric phenols having at least one aromatic ring (phenol, bisphenol A, phenol novolak, and alkylene oxide adducts thereof), and the like.

As the alicyclic epoxy compounds, exemplified are compounds obtained by epoxidizing a compound having at least one cyclohexene or cyclopentene ring with an oxidant (such as 3,4-epoxycyclohexylmethyl-3,4-epoxycyclohexanecarboxylate), and the like.

As the aliphatic epoxy compounds, exemplified are polyglycidyl ethers of aliphatic polyhydric alcohols or their alkylene oxide adducts (1,4-butanediol diglycidyl ether, 1,6-hexanediol diglycidyl ether, etc.), polyglycidyl esters of aliphatic polybasic acids (diglycidyl tetrahydrophthalate, etc.), epoxy compounds of long-chain unsaturated compounds (epoxidized soybean oil, epoxidized polybutadiene, etc.), and the like.

As the oxetane compounds, known compounds can be used, and for example, exemplified are 3-ethyl-3-hydroxymethyloxetane, 2-ethylhexyl(3-ethyl-3-oxetanylmethyl) ether, 2-hydroxyethyl(3-ethyl-3-oxetanylmethyl) ether, 2-hydroxypropyl(3-ethyl-3-oxetanylmethyl) ether, 1,4-bis[(3-ethyl-3-oxetanylmethoxy)methyl]benzene, oxetanyl silsesquioxetane, phenol novolac oxetane, and the like.

As the ethylenic unsaturated compounds, known cationic polymerizable monomers and the like can be used, including aliphatic monovinyl ethers, aromatic monovinyl ethers, polyfunctional vinyl ethers, styrenes cationic polymerizable nitrogen-containing monomers, etc.

As the aliphatic monovinyl ethers, exemplified are methyl vinyl ether, ethyl vinyl ether, butyl vinyl ether, cyclohexyl vinyl ether, and the like.

As the aromatic monovinyl ethers, exemplified are 2-phenoxyethyl vinyl ether, phenyl vinyl ether, p-methoxyphenyl vinyl ether, and the like.

As the polyfunctional vinyl ethers, exemplified are butanediol-1,4-divinyl ether, triethylene glycol divinyl ether, and the like.

As the styrenes, exemplified are styrene, α-methyl styrene, p-methoxy styrene, p-tert-butoxy styrene, and the like.

As the Cationic polymerizable nitrogen-containing monomers, exemplified are N-vinyl carbazole, N-vinylpyrrolidone, and the like.

As the bicycloorthoesters, exemplified are 1-phenyl-4-ethyl-2,6,7-trioxabicyclo[2.2.2]octane, 1-ethyl-4-hydroxymethyl-2,6,7-trioxabicyclo-[2.2.2]octane, and the like.

As the spiroorthocarbonates, exemplified are 1,5,7,11-tetraoxaspiro[5.5]undecane, 3,9-dibenzyl-1,5,7,11-tetraoxaspiro[5.5]undecane, and the like.

As the spiroorthoesters, exemplified are 1,4,6-trioxaspiro[4.4]nonane, 2-methyl-1,4,6-trioxaspiro[4.4]nonane, 1,4,6-trioxaspiro[4.5]decane, and the like.

Among these cationic polymerizable compounds, epoxy compounds, oxetane compounds and vinyl ethers are preferred, and epoxy compounds and oxetane compounds are more preferred.

By containing an epoxy compound having an isocyanurate skeleton as the cationic polymerizable compound, the dielectric constant and dielectric loss tangent of the cured film obtained by curing the resin composition can be kept low while maintaining the cationic polymerizability. Furthermore, when developing with an alkaline aqueous solution, although the reason is unclear, by being compatible with the soluble polymer compound (a) which is alkaline soluble, but the resin composition itself does not dissolve in the alkaline aqueous solution, the resin composition can be patterned with the alkaline aqueous solution without hindering its alkaline solubility.

As the epoxy compounds containing an isocyanurate skeleton, exemplified are triglycidyl isocyanurates such as TEPIC-S, TEPIC-L, TEPIC-VL, TEPIC-PASB26L, TEPIC-PASB22, TEPIC-FL, TEPIC-UC (product names, all manufactured by Nissan Chemical Industries, Ltd.), and the like.

When the epoxy compound having an isocyanurate skeleton is contained as the cationic polymerizable compound, the content is preferably 40% by mass or more, more preferably 60% by mass or more, with respect to 100% by mass of the total of the cationic polymerizable compounds. Further, the upper limit of the content of the epoxy compound having an isocyanurate skeleton is 100% by mass.

Further, by using a polyfunctional epoxy compound that is liquid at normal temperature as the cationic polymerizable compound, the compatibility with the (a) soluble polymer compound is improved, and fine pattern processability is obtained, which is preferable. In this case, the polyfunctional epoxy compound preferably has an epoxy equivalent of 80 g/eq. or more and 160 g/eq. or less. By having an epoxy equivalent of 80 g/eq. or more and 160 g/eq. or less, when made into a cured film, the heat resistance and chemical resistance of the cured film can be improved. The epoxy equivalent of the polyfunctional epoxy compound is more preferably 80 g/eq. or more and 150 g/eq. or less, and further preferably 85 g/eq. or more and 130 g/eq. or less.

As the polyfunctional epoxy compounds that are liquid at normal temperature and have an epoxy equivalent of 80 g/eq. or more and 160 g/eq. or less, for example, exemplified are TEPIC-VL (trade name, supplied by Nissan Chemical Industries, Ltd.), bisphenol A type epoxy compounds, bisphenol F type epoxy compounds, Showfree BATG, and Showfree PETG (trade names, all supplied by Showa Denko K.K.), and the like.

The cationic polymerizable compounds may be used alone or in combination of two or more.

The content of the cationic polymerizable compound is preferably 30 parts by mass or more, more preferably 50 parts by mass or more, when the soluble polymer compound (a) is taken as 100 parts by mass, from the viewpoint of showing sufficient cationic curability and improving pattern processability. On the other hand, when made into a film form, that is, a resin composition coating film, from the viewpoint of the absence of tack on the surface of the resin composition coating film and the ease of handling, and from the viewpoint of improving the strength and elongation of the cured film, the content of the cationic polymerizable compound is preferably 200 parts by mass or less, more preferably 150 parts by mass or less, when the soluble polymer compound (a) is taken as 100 parts by mass.

The photo cationic polymerization initiator generates an acid by the action of light, thereby causing cationic polymerization. The photo cationic polymerization initiator is preferably an onium salt.

Specifically, as the photo cationic polymerization initiator, for example, exemplified are aromatic iodonium complex salts, aromatic sulfonium complex salts, aromatic borate complex salts, aromatic gallate complex salts, and the like.

As specific examples of aromatic iodonium complex salts, exemplified are diphenyl iodonium tetrakis(pentafluoro phenyl) borate, diphenyl iodonium hexafluorophosphate, diphenyl iodonium hexafluoro antimonate, di(4-nonylphenyl) iodonium hexafluoro phosphate, and the like.

As specific examples of the photo cationic polymerization initiator other than the above-described aromatic iodonium complex salts, for example, exemplified are benzenesulfonate (4-hydroxyphenyl)dimethyl sulfonium, benzenesulfonate ((4-((methoxycarbonyl)oxy)phenyl)dimethyl sulfonium, benzenesulfonate benzyl(4-hydroxyphenyl)methyl sulfonium, benzenesulfonate benzyl(4-((methoxycarbonyl)oxy)phenyl)methyl sulfonium, benzenesulfonate (4-hydroxyphenyl)methyl((2-methylphenyl)methyl) sulfonium, camphor sulfonate (4-hydroxyphenyl)dimethyl sulfonium, camphor sulfonate (4-((methoxycarbonyl)oxy)phenyl)dimethyl sulfonium, benzenesulfonate benzyl(4-camphor sulfonate benzyl(4-hydroxyphenyl)methyl sulfonium, ((methoxycarbonyl)oxy)phenyl)methyl sulfonium, camphor sulfonate (4-hydroxyphenyl)methyl((2-methylphenyl)methyl) sulfonium, trifluoro methane sulfonate (4-hydroxyphenyl)dimethyl sulfonium, trifluoro methane sulfonate benzyl(4-hydroxyphenyl)methyl sulfonium, trifluoro methane sulfonate benzyl(4-((methoxycarbonyl)oxy)phenyl)methyl sulfonium, trifluoro methane sulfonate (4-hydroxyphenyl)methyl((2-methylphenyl)methyl) sulfonium, “SAN-AID” (registered trademark), SI-145, SI-200, SI-250, SI-B2A, SI-B3A, SI-B3, SI-B4, SI-B5 (supplied by Sanshin Chemical Industry Co., Ltd.), CPI-310FG (trade name, supplied by San-Apro Co., Ltd.), and the like. These photo cationic polymerization initiators may be used alone, or two or more types may be used in combination.

By using an onium salt as a photo cationic polymerization initiator, when a cyclic ether compound is used, the initiation reaction of cationic polymerization can proceed sufficiently.

The content of the photo cationic polymerization initiator is preferably 0.3 parts by mass or more, more preferably 0.5 parts by mass or more, and further preferably 0.7 parts by mass or more, with respect to 100 parts by mass of the cationic polymerizable compound. This allows the cationic polymerizable compound to exhibit sufficient curability and improves pattern processability. On the other hand, from the viewpoint of improving the storage stability of the resin composition before curing, the content of the photo cationic polymerization initiator is preferably 10 parts by mass or less, more preferably 8 parts by mass or less, with respect to 100 parts by mass of the cationic polymerizable compound.

The resin composition of the present invention may contain a thermal crosslinking agent. The thermal crosslinking agent is preferably a compound having an alkoxymethyl group or a methylol group.

As examples of compounds having an alkoxymethyl group or a methylol group, exemplified are DML-PC, DML-PEP, DML-OC, DML-OEP, DML-34X, DML-PTBP, DML-PCHP, DML-OCHP, DML-PFP, DML-PSBP, DML-POP, DML-MBOC, DML-MBPC, DML-MTrisPC, DML-BisOC-Z, DML-BisOCHP-Z, DML-BPC, DML-BisOC-P, DMOM-PC, DMOM-PTBP, DMOM-MBPC, TriML-P, TriML-35XL, TML-HQ, TML-BP, TML-pp-BPF, TML-BPE, TML-BPA, TML-BPAF, TML-BPAP, TMOM-BP, TMOM-BPE, TMOM-BPA, TMOM-BPAF, TMOM-BPAP, HML-TPPHBA, HML-TPHAP, HMOM-TPPHBA, HMOM-TPHAP (all trade names, supplied by Honshu Chemical Industry Co., Ltd.), NIKALAC (registered trademark) MX-290, NIKALAC MX-280, NIKALAC MW-100 LM, NIKALAC MX-750 LM (all trade names, supplied by Sanwa Chemical Co., Ltd.), and the like.

The resin composition of the present invention may further contain a silane compound. By containing a silane compound, adhesion of the resin composition coating film described later is improved. As specific examples of the silane compound, can be exemplified N-phenyl aminoethyl trimethoxy silane, N-phenyl aminoethyl triethoxy silane, N-phenyl aminopropyl trimethoxy silane, N-phenyl aminopropyl triethoxy silane, N-phenyl aminobutyl trimethoxy silane, N-phenyl aminobutyl triethoxy silane, vinyl trimethoxy silane, vinyl triethoxy silane, vinyl trichloro silane, vinyl tris(β-methoxy ethoxy) silane, 3-methacryloxy propyl trimethoxy silane, 3-acryloxy propyl trimethoxy silane, p-styryl trimethoxy silane, 3-methacryloxy propyl methyl dimethoxy silane, 3-methacryloxy propyl methyl diethoxy silane, 2-(3,4-epoxycyclohexyl)ethyl trimethoxy silane, and the like.

Furthermore, the resin composition of the present invention may contain, as needed, a surfactant for the purpose of improving wettability with a support material, an ester such as ethyl lactate or propylene glycol monomethyl ether acetate, an alcohol such as ethanol, a ketone such as cyclohexanone or methyl isobutyl ketone, or an ether such as tetrahydrofuran or dioxane. In addition, for the purpose of suppressing the thermal expansion coefficient, increasing the dielectric constant, decreasing the dielectric constant, or the like, inorganic particles such as silicon dioxide, titanium dioxide, or the like, or polyimide powder, may be contained.

The resin composition of the present invention is not limited in shape before curing, and it may be, for example, a varnish-like or film-like. Here, the resin composition of the present invention made into the form of a film is also called as the negative-type photosensitive resin composition coating film of the present invention (hereinafter, also simply referred to as “resin composition coating film”).

Further, the negative type photosensitive resin composition film of the present invention (hereinafter, also simply referred to as “resin composition film”) has a film-shaped resin composition of the present invention and a support material, that is, the resin composition film of the present invention is a resin composition film having a resin composition coating film formed from the resin composition of the present invention and a support material. Therefore, the resin composition film of the present invention is a resin composition film in the form of a film formed on a support material, that is, a resin composition film having a resin composition coating film formed from the resin composition of the present invention on a support.

When the resin composition of the present invention is used in the form of a varnish, it can be used as a form where the components (a), (b) and (c) and the components added as needed are dissolved in an organic solvent. Also, the resin composition film can be obtained, for example, by applying the resin composition of the present invention onto a support material and then drying it as needed.

Next, a method for producing a resin composition film using the resin composition of the present invention will be explained. The resin composition film of the present invention is a film comprising the resin composition of the present invention, and can be obtained, for example, by applying a varnish of the resin composition of the present invention (hereinafter, also simply referred to as “resin composition varnish”) onto a support material and then drying it. The organic solvent used in the resin composition varnish may be any solvent that dissolves the resin composition.

As the organic solvent, specifically exemplified are ethers such as ethylene glycol monomethyl ether, ethylene glycol monoethyl ether, propylene glycol monomethyl ether, propylene glycol monoethyl ether, ethylene glycol dimethyl ether, ethylene glycol diethyl ether, and ethylene glycol dibutyl ether; acetates such as ethylene glycol monoethyl ether acetate, propylene glycol monomethyl ether acetate, propyl acetate, butyl acetate, isobutyl acetate, 3-methoxybutyl acetate, 3-methyl-3-methoxybutyl acetate, methyl lactate, ethyl lactate, and butyl lactate; ketones such as acetone, methyl ethyl ketone, acetyl acetone, methyl propyl ketone, methyl butyl ketone, methyl isobutyl ketone, cyclopentanone, and 2-heptanone; alcohols such as butyl alcohol, isobutyl alcohol, pentanol, 4-methyl-2-pentanol, 3-methyl-2-butanol, 3-methyl-3-methoxy butanol, and diacetone alcohol; aromatic hydrocarbons such as toluene and xylene; and others such as N-methyl-2-pyrrolidone, N-cyclohexyl-2-pyrrolidone, N,N-dimethyl formamide, N,N-dimethyl acetamide, dimethyl sulfoxide, γ-butyrolactone, and the like.

The amount of the organic solvent added is preferably adjusted so that the solids concentration is 20% by weight or more and 70% by weight or less, when additives other than the organic solvent are referred to as the solids content.

The resin composition varnish may be filtered using a filter paper or a filter. The filtration method is not particularly limited, but a method of filtering by pressure filtration using a filter with a retention particle size of 0.4 to 10 μm is preferred.

As described above, the resin composition film of the present invention is a resin composition film comprising the resin composition of the present invention, and therefore, the resin composition film of the present invention is, for example, formed by forming a resin composition coating film on a support material. The support material is not particularly limited, and various films that are usually commercially available, such as polyethylene terephthalate (PET) film, polyphenylene sulfide film, and polyimide film, can be used. The joint surface between the support material and the resin composition coating film may be surface-treated with silicone, a silane coupling agent, an aluminum chelating agent, polyurea, etc. to improve adhesion and peelability. Further, the thickness of the support material is not particularly limited, but it is preferably in the range of 10 to 100 μm from the viewpoint of workability.

The resin composition film of the present invention may have a protective film on the resin composition coating film in order to protect the surface. By this, the surface of the resin composition film can be protected from contaminants such as dust and dirt in the atmosphere. As the protective film, polyolefin films and polyester films can be exemplified. It is preferred that the protective film has a small adhesive force with the resin composition film.

As the methods for applying the resin composition varnish to a support material, exemplified are spin coating using a spinner, spray coating, roll coating, screen printing, blade coater, die coater, calendar coater, meniscus coater, bar coater, roll coater, comma roll coater, gravure coater, screen coater, slit die coater, etc. Further, the coating film thickness varies depending on the coating method, the solid content concentration of the resin composition, the viscosity, etc., but it is usually preferred that the film thickness after drying is 0.5 μm or more and 100 μm or less.

For drying, an oven, a hot plate, infrared rays, etc. can be used. The drying temperature and drying time may be within a range capable of volatilizing the organic solvent, and it is preferable to appropriately set a range in which the resin composition film becomes in an uncured or semi-cured state. Specifically, it is preferred to perform drying at a range of 40° C. to 120° C. for one minute to several tens of minutes. In addition, these temperatures may be combined to elevate the temperature stepwise, and for example, heat treatment may be performed at 70° C., 80° C., and 90° C. for one minute each.

Next, a method for patterning the resin composition varnish or resin composition film using the resin composition of the present invention, and a method for thermocompression bonding it to another member will be explained described with reference to examples.

First, a method for forming a resin composition coating film on a substrate using the resin composition or resin composition film of the present invention will be explained.

In case of forming a resin composition coating film on a substrate using the resin composition varnish, first, the resin composition varnish is applied to the substrate. As the application method, exemplified are spin coating using a spinner, spray coating, roll coating, screen printing, and the like. Further, the coating thickness varies depending on the application method, the solid concentration and viscosity of the resin composition, and usually, it is preferred to apply it so that the film thickness after drying becomes 0.5 μm or more and 100 μm or less. Next, the substrate to which the resin composition varnish has been applied is dried to form a resin composition coating film.

For the drying, an oven, a hot plate, infrared rays, etc., can be used. The drying temperature and drying time may be within a range that allows the organic solvent to volatilize, and it is preferred to appropriately set a range in which the resin composition coating film becomes in an uncured or semi-cured state. Specifically, drying is preferably performed within a range of 50 to 150° C. for one minute to several hours.

On the other hand, in case of using a resin composition film, if a protective film is present, it is peeled off, the resin composition film is placed opposite a substrate, and the resin composition film is bonded by thermocompression to form a resin composition coating film on the substrate. Thermocompression bonding can be performed by a heat press process, a heat lamination process, a heat vacuum lamination process, or the like. The bonding temperature is preferably 40° C. or higher in terms of adhesion to the substrate and embeddability. In addition, in order to prevent the resin composition film from curing during bonding, which deteriorates the resolution of pattern formation in the exposure and development process, the bonding temperature is preferably 150° C. or lower.

In either case, the substrate used may include silicon wafers, ceramics, gallium arsenide, organic circuit boards, inorganic circuit boards, and these substrates on which circuit components are disposed, but it is not limited thereto.

As examples of the organic circuit boards, exemplified are glass-based copper-clad laminates such as glass cloth/epoxy copper-clad laminates, composite copper-clad laminates such as glass nonwoven fabric/epoxy copper-clad laminates, heat-resistant/thermoplastic substrates such as polyetherimide resin substrates, polyether ketone resin substrates, and polysulfone resin substrates, and flexible substrates such as polyester copper-clad film substrates and polyimide copper-clad film substrates.

Further, as examples of inorganic circuit boards, exemplified are ceramic boards such as alumina boards, aluminum nitride boards, and silicon carbide boards, and metal boards such as aluminum-based boards and iron-based boards. As examples of materials constituting the circuit, exemplified are conductors containing metals such as silver, gold, and copper, resistors containing inorganic oxides or the like, low dielectrics containing glass-based materials and/or resins or the like, high dielectrics containing resins or high-dielectric-constant inorganic particles or the like, insulators containing glass-based materials or the like, etc.

Next, the resin composition coating film formed by the above-described method is exposed to chemical radiation through a mask having a desired pattern. The chemical radiation used for the exposure includes ultraviolet rays, visible light, electron beam, X-ray, etc., and in the present invention, it is preferred to use the i-ray (365 nm), h-ray (405 nm), and g-ray (436 nm) of a mercury lamp. In the resin composition film, if the support material is a material that is transparent to these rays, the exposure may be performed without peeling the support material from the resin composition film.

To form a pattern, after the exposure, an unexposed portion is removed with a developer. As the developer, an aqueous solution of tetramethylammonium hydroxide, and an aqueous solution of a compound exhibiting alkalinity such as diethanolamine, diethyl aminoethanol, sodium hydroxide, potassium hydroxide, sodium carbonate, potassium carbonate, triethylamine, diethylamine, methylamine, dimethylamine, dimethyl aminoethyl acetate, dimethyl aminoethanol, dimethyl aminoethyl methacrylate, cyclohexylamine, ethylenediamine, or hexamethylenediamine, are preferred. Further, as the case may be, these aqueous alkaline solutions may contain polar solvents such as N-methyl-2-pyrrolidone, N,N-dimethylformamide, N,N-dimethylacetamide, dimethyl sulfoxide, γ-butyrolactone, or dimethylacrylamide; alcohols such as methanol, ethanol, or isopropanol; esters such as ethyl lactate or propylene glycol monomethyl ether acetate; or ketones such as cyclopentanone, cyclohexanone, isobutyl ketone, or methyl isobutyl ketone; either alone or in combination.

The development can be carried out by methods for spraying the developer on the coating film surface, piling the developer on the coating film surface, immersing it in the developer, or immersing it in the developer and applying ultrasonic waves, etc. The development conditions, such as the development time, development steps, and developer temperature, may be any conditions that allow the unexposed areas to be removed and a pattern to be formed.

After the development, it is preferred to carry out a rinsing treatment with water. Here, too, the rinsing treatment may be carried out by adding alcohols such as ethanol and isopropyl alcohol or esters such as ethyl lactate and propylene glycol monomethyl ether acetate to water.

As needed, a baking treatment may be performed before development. By this, the resolution of the pattern after development may be improved and the allowable range of development conditions may be increased. The baking treatment temperature is preferably in the range of 50 to 180° C., more preferably in the range of 60 to 120° C. The time is preferably 5 seconds to several hours.

After the pattern formation, unreacted cationic polymerizable compound and photo cationic polymerization initiator remain in the resin composition coating film. Therefore, there is a case where these are thermally decomposed and gas generates during thermocompression bonding or curing. To avoid this, it is preferred to irradiate the entire surface of the resin composition coating film after pattern formation with the above-described exposure light, thereby generating acid from the photo cationic polymerization initiator. By this, the reaction of the unreacted cationic polymerizable compound proceeds during thermocompression bonding or curing, and the generation of gas resulting from thermal decomposition can be suppressed.

After the development, a temperature of 150 to 500° C. is applied to proceed with the thermal crosslinking reaction. By the crosslinking, heat resistance and chemical resistance can be improved. This heat treatment method can be selected from a method in which a temperature is selected and the temperature is elevated stepwise, or a method in which a certain temperature range is selected and the temperature is elevated continuously for 5 minutes to 5 hours. As an example of the former, exemplified is a method in which heat treatment is performed at 130° C. and 200° C. for 30 minutes each. As an example of the latter, exemplified is a method in which the temperature is elevated linearly from a room temperature to 400° C. over a period of 2 hours.

The cured film of the present invention is a cured film obtained by curing the resin composition of the present invention or the resin composition film of the present invention. The cured film of the present invention can be used in electronic components such as semiconductor devices. Namely, the electronic component of the present invention contains the cured film of the present invention.

A semiconductor device, which is one of the electronic components, indicates a general device which can function by utilizing the properties of a semiconductor element. Electro-optical devices or semiconductor circuit boards in which a semiconductor element is connected to a substrate, stacks of a plurality of semiconductor elements, and electronic devices that contain these, are all included in the semiconductor device. Further, electronic components such as multilayer wiring boards for connecting semiconductor elements are also included in the semiconductor device. Specifically, the electronic component of the present invention is suitably used for applications such as a passivation film for a semiconductor, a surface protection film for a semiconductor element, an interlayer insulating film between a semiconductor element and wiring, an interlayer insulating film between a plurality of semiconductor elements, an interlayer insulating film between wiring layers of multilayer wiring for high-density mounting, and an insulating layer for an organic electroluminescent element, but is not limited thereto and can be used for various applications.

### EXAMPLES

Hereinafter, the present invention will be specifically described based on examples, but the present invention is not limited thereto.

### <Evaluation of Adhesion>

For the resin composition film produced in each of Examples and Comparative Examples, if there was a protective film, it was peeled off, and the peeled surface was laminated on a 4-inch silicon wafer using a vacuum diaphragm type laminator (supplied by Meiki Seisakusho Co., Ltd., MVLP-500/600) under the conditions of upper and lower heating plate temperature: 80° C., vacuum drawing time: 20 seconds, vacuum pressing time: 30 seconds, and application pressure: 0.3 MPa, to form a resin composition film on the silicon wafer. Then, if there was a support film, it was peeled off, and then exposure was performed with an exposure amount of 500 mJ/cm² (i-ray equivalent, full wavelength exposure) using an ultra-high pressure mercury lamp. After the exposure, post-exposure heating was performed on a hot plate at 80° C. for 10 minutes. Then, using an inert oven (INL-60, supplied by Koyo Thermo Systems Co., Ltd.), after the temperature was elevated from a room temperature to 200° C. over 60 minutes in an N₂ atmosphere (oxygen concentration: 20 ppm or less), it was heat-treated at 200° C. for 60 minutes to obtain a cured film of the resin composition film formed on the silicon wafer. The obtained cured film was treated in an unsaturated pressure cooker test (130° C., humidity: 85%) for 96 hours. A cross-cut test was performed on the sample after the test, and it was evaluated with four ranks as follows.
A+: A case not corresponding to A, B, or C, and no peeling was observed in any of the lattices.
A: A case not corresponding to B or C, and slight peeling was observed near the intersections of the lattices.
B: A case not corresponding to C, partial peeling was observed along the lattice lines.
C: Peeled off entirely.

### <Evaluation of Storage Stability>

For the resin composition film produced in each of Examples and Comparative Examples, the melt viscosity was measured using a rheometer (MCR-302, supplied by Anton Paar Co., Ltd.) under conditions of a frequency of 0.2 Hz and a strain of 1%. The melt viscosity at 80° C. at this time was taken as η₀. Next, the resin composition film was stored at 25° C. for one week, and the melt viscosity was measured in the same manner as above. The melt viscosity at 80° C. at this time was taken as η₁. Using the melt viscosities η₀ and η₁, the rate of change in melt viscosity was calculated according to the following equation (2).

$$( Rate of change in melt viscosity ) = 100 * {η}_{1} / {η}_{0} ( \% ) \qquad Equation ( 2 )$$

The rate of change in melt viscosity was evaluated with the following four ranks.
A+: 120% or less
A: 121% to 150%
B: 151% to 200%
C: 201% or more

### <Evaluation of Pattern Processability>

The resin composition film was formed on a silicon wafer in the same manner as in the evaluation method of adhesion. Then, after peeling off the support film, a mask having a pattern with via sizes of 30 μmφ, 20 μmφ, and 10 μmφ was set in an exposure device, and exposure was performed with an exposure amount of 1,000 mJ/cm² (i-ray equivalent, full wavelength exposure) using an ultra-high pressure mercury lamp under the condition of an exposure gap of 100 μm between the mask and the photosensitive resin composition film. After the exposure, post-exposure heating was performed on a hot plate at 120° C. for 10 minutes. Thereafter, the unexposed part was removed by dip development using a 2.38 mass % aqueous solution of tetramethyl ammonium hydroxide, and rinsed with water. The development time was set to twice the time when the unexposed part was completely dissolved.

The patterns thus obtained were observed by an optical microscope, and the smallest size when there was no abnormality such as clogging in the pattern was taken as the minimum opening size. In this case, where no abnormality such as clogging occurred in any of the patterns and no opening was formed, the minimum opening size was taken as 0. In addition, the film thickness after development was measured, and the residual film ratio was calculated from the following equation (3).

$$Residual film ratio = 100 * ( film thickness after development ) / ( film thickness before development ) ( \% ) \qquad Equation ( 3 )$$

Based on the minimum opening size and the residual film ratio, the pattern processability was evaluated with the following four ranks.
A+: Residual film ratio is 90% or more, and the minimum opening size is 10 μmφ
A: Residual film ratio is 90% or more, and the minimum opening size is 20 μmφ
B: Residual film ratio is 90% or more, and the minimum opening size is 30 μmφ
C: Residual film ratio is less than 90% or the minimum opening size is 0

### Synthesis Example 1: Synthesis of Soluble Polymer Compound (a-1)

Under a dry nitrogen stream, 2,2-bis(3-amino-4-hydroxyphenyl) hexafluoro propane (hereinafter, referred to as BAHF) (29.30 g, 0.08 mol) was added to 80 g of γ-butyrolactone (hereinafter, referred to as GBL) and dissolved by stirring at 120° C. Next, 4-(2,5-dioxotetrahydrofuran-3-yl)-1,2,3,4-tetrahydronaphthalene-1,2-dicarboxylic dianhydride (hereinafter, referred to as TDA-100) (27.02 g, 0.09 mol) and X-12-967C (5.24 g, 0.02 mol) were added together with 20 g of GBL and stirred at 120° C. for 1 hour. Then, the mixture was stirred at 200° C. for 4 hours to obtain a reaction solution. Next, the reaction solution was poured into 3 L of water and a white precipitate was collected. The precipitate was collected by filtration, washed three times with water, and then dried in a vacuum dryer at 80° C. for 5 hours.

### Synthesis Example 2: Synthesis of Soluble Polymer Compound (a-2)

A soluble polymer compound (a-2) was obtained in the same manner as in Synthesis Example 1, except that the amount of BAHF added was changed to 34.79 g, 0.095 mol.

### Synthesis Example 3: Synthesis of Soluble Polymer Compound (a-3)

A soluble polymer compound (a-3) was obtained in the same manner as in Synthesis Example 1, except that the amount of BAHF added was changed to 36.08 g, 0.0985 mol.

### Synthesis Example 4: Synthesis of Soluble Polymer Compound (a-4)

A soluble polymer compound (a-4) was obtained in the same manner as in Synthesis Example 1, except that the amount of BAHF added was changed to 23.81 g, 0.065 mol.

### Synthesis Example 5: Synthesis of Soluble Polymer Compound (a-5)

A soluble polymer compound (a-5) was obtained in the same manner as in Synthesis Example 1, except that the amount of BAHF added was changed to 20.14 g, 0.055 mol.

### Synthesis Example 6: Synthesis of Soluble Polymer Compound (a-6)

A soluble polymer compound (a-6) was obtained in the same manner as in Synthesis Example 1, except that the amount of X-12-967C added was changed to 1.31 g, 0.005 mol.

### Synthesis Example 7: Synthesis of Soluble Polymer Compound (a-7)

A soluble polymer compound (a-7) was obtained in the same manner as in Synthesis Example 1, except that the amount of X-12-967C added was changed to 0.52 g, 0.002 mol.

### Synthesis Example 8: Synthesis of Soluble Polymer Compound (a-8)

A soluble polymer compound (a-8) was obtained in the same manner as in Synthesis Example 1, except that the amount of X-12-967C added was changed to 10.49 g, 0.04 mol.

### Synthesis Example 9: Synthesis of Soluble Polymer Compound (a-9)

A soluble polymer compound (a-9) was obtained in the same manner as in Synthesis Example 1, except that the amount of X-12-967C added was changed to 15.74 g, 0.06 mol.

### Synthesis Example 10: Synthesis of Soluble Polymer Compound (a-10)

A soluble polymer compound (a-10) was obtained in the same manner as in Synthesis Example 1, except that BAHF was replaced with 30.44 g, 0.08 mol of 9,9-bis(3-amino-4-hydroxyphenyl) fluorene (hereinafter, referred to as FDA).

### Synthesis Example 11: Synthesis of Soluble Polymer Compound (a-11)

Under a dry nitrogen stream, BAHF (29.30 g, 0.08 mol) was added to 80 g of GBL and dissolved by stirring at 120° C. Next, TDA-100 (30.02 g, 0.10 mol) was added together with 20 g of GBL and stirred at 120° C. for 1 hour. Then, the mixture was stirred at 200° C. for 4 hours to obtain a reaction solution. Next, the reaction solution was poured into 3 L of water to collect a white precipitate. This precipitate was collected by filtration, washed three times with water, and then dried in a vacuum dryer at 80° C. for 5 hours.

### Synthesis Example 12: Synthesis of Soluble Polymer Compound (a-12)

Under a dry nitrogen stream, BAHF (29.30 g, 0.08 mol) was added to 80 g of GBL and dissolved by stirring at 120° C. Next, TDA-100 (27.02 g, 0.09 mol) and X-12-967C (5.25 g, 0.02 mol) were added together with 20 g of GBL and stirred at 120° C. for 1 hour to obtain a reaction solution. Next, the reaction solution was poured into 3 L of water to collect a white precipitate. This precipitate was collected by filtration, washed three times with water, and then dried in a vacuum dryer at 80° C. for 5 hours.

Since the polymer compounds synthesized in Synthesis Examples 1 to 12 were dissolved at an amount of 0.1 g or more in 100 g of γ-butyrolactone solution at 25° C., they exhibited solubility.

### Example 1

1 g of the soluble polymer compound (a-1) obtained in Synthesis Example 1 as the component (a), 1.2 g of TEPIC-VL (trade name, supplied by Nissan Chemical Industries, Ltd.) as the polymerizable compound (b), and 0.06 g of CPI-310FG (trade name, supplied by San-Apro Co., Ltd.) as the photopolymerization initiator (c) were dissolved in GBL. The amount of solvent added was adjusted so that the solid content concentration was 50 wt %, when additives other than the solvent were referred to as the solid content. Thereafter, the mixture was pressure-filtered using a filter with a retention particle size of 1 μm to obtain a resin composition varnish.

The obtained resin composition varnish was applied onto a silicon wafer using a spinner at 1,500 rpm for 30 seconds, and dried on a hot plate at 80° C. for 3 minutes to form a resin composition coating film on the silicon wafer. Next, using the obtained resin composition coating film, evaluations of adhesion, storage stability, and pattern processability were performed as aforementioned. The results are shown in Table 1.

### Examples 2 to 13

The resin composition varnishes were prepared in the same manner as in Example 1, except that the components (a) to (c) were changed to the following compounds and their mixing ratios were changed as shown in Table 1. The adhesion, storage stability, and pattern processability were evaluated as aforementioned. The results are shown in Tables 1 and 2.

### Comparative Examples 1 to 3

The resin composition varnishes were prepared in the same manner as in Example 1, except that the components (a) to (c) and other components were changed to the following compounds and their mixing ratios were changed as shown in the Table. The adhesion, storage stability, and pattern processability were evaluated as aforementioned. The results are shown in Table 2.

TABLE 1

| | | Example 1 | Example 2 | Example 3 | Example 4 | Example 5 | Example 6 | Example 7 | Example 8 |
|---|---|---|---|---|---|---|---|---|---|
| (a) Soluble polymer | (a-1) | 100 | — | — | — | — | — | — | — |
| compound | (a-2) | — | 100 | — | — | — | — | — | — |
| | (a-3) | — | — | 100 | — | — | — | — | — |
| | (a-4) | — | — | — | 100 | — | — | — | — |
| | (a-5) | — | — | — | — | 100 | — | — | — |
| | (a-6) | — | — | — | — | — | 100 | — | — |
| | (a-7) | — | — | — | — | — | — | 100 | — |
| | (a-8) | — | — | — | — | — | — | — | 100 |
| | (a-9) | — | — | — | — | — | — | — | — |
| | (a-10) | — | — | — | — | — | — | — | — |
| | (a-11) | — | — | — | — | — | — | — | — |
| | (a-12) | — | — | — | — | — | — | — | — |
| (b) Polymerizable | TEPIC-VL | 120 | — | 80 | 120 | 120 | 120 | 120 | 120 |
| compound | ETERNACOLL | — | 100 | — | — | — | — | — | — |
| | OXBP | | | | | | | | |
| (c) Photopolymerization | CPI-310FG | 6 | 6 | 6 | 6 | 6 | 6 | 6 | 6 |
| initiator | | | | | | | | | |
| Silane compound | X-12-967C | — | — | — | — | — | — | — | — |

| | | | | | | | | |
|---|---|---|---|---|---|---|---|---|
| Evaluation of adhesion | A+ | A+ | A+ | A+ | A+ | A | B | A+ |
| Evaluation of storage stability | A+ | A+ | A+ | A+ | A | A+ | A+ | A+ |
| Evaluation of pattern | A+ | A+ | A | A+ | A+ | A+ | A+ | A+ |
| processability | | | | | | | | |

TABLE 2

| | | Example | Example | Example | Example | Example | Comparative | Comparative | Comparative |
|---|---|---|---|---|---|---|---|---|---|
| | | 9 | 10 | 11 | 12 | 13 | Example 1 | Example 2 | Example 3 |
| (a) Soluble polymer | (a-1) | — | — | 100 | 100 | 100 | — | — | — |
| compound | (a-2) | — | — | — | — | — | — | — | — |
| | (a-3) | — | — | — | — | — | — | — | — |
| | (a-4) | — | — | — | — | — | — | — | — |
| | (a-5) | — | — | — | — | — | — | — | — |
| | (a-6) | — | — | — | — | — | — | — | — |
| | (a-7) | — | — | — | — | — | — | — | — |
| | (a-8) | — | — | — | — | — | — | — | — |
| | (a-9) | 100 | — | — | — | — | — | — | — |
| | (a-10) | — | 100 | — | — | — | — | — | — |
| | (a-11) | — | — | — | — | — | 100 | 100 | — |
| | (a-12) | — | — | — | — | — | — | — | 100 |
| (b) Polymerizable | TEPIC-VL | 120 | 120 | — | 80 | 150 | 120 | 120 | 120 |
| compound | ETERNACOLL | — | — | 100 | — | — | — | — | — |
| | OXBP | | | | | | | | |
| (c) Photopolymerization | CPI-310FG | 6 | 6 | 6 | 6 | 6 | 6 | 6 | 6 |
| initiator | | | | | | | | | |
| Silane compound | X-12-967C | — | — | — | — | — | — | 6 | — |

| | | | | | | | | |
|---|---|---|---|---|---|---|---|---|
| Evaluation of adhesion | A+ | A+ | A+ | A+ | A+ | C | A+ | A |
| Evaluation of storage | B | A+ | A+ | A+ | A+ | A+ | C | C |
| stability | | | | | | | | |
| Evaluation of pattern | A+ | A+ | A+ | A+ | A+ | A+ | A+ | C |
| processability | | | | | | | | |

The structures of the compounds used in each of the Synthesis Examples, Examples and Comparative Examples are shown below.

### (a) Soluble Polymer Compound:

a-1 to a-10: Soluble polymer compounds containing a structure having a repeating unit represented by chemical formula (1), containing a structure derived from an acid anhydride silane residue, and containing a structure represented by chemical formula (2), in which the acid anhydride silane residue is derived from a structure represented by chemical formula (4).
a-11: A soluble polymer compound containing a structure having a repeating unit represented by chemical formula (1).
a-12: A soluble polymer compound that does not contain a structure having a repeating unit represented by chemical formula (1) and has a structure derived from an acid anhydride silane residue represented by chemical formula (4).

### (b) Polymerizable Compound:

TEPIC-VL (supplied by Nissan Chemical Industries, Ltd.), liquid at normal temperature, epoxy equivalent=128 g/eq.
ETERNACOLL OXBP (supplied by UBE Co., Ltd.), an oxetane compound.

### (c) Photopolymerization Initiator:

CPI-310FG (onium salt-based cationic polymerization initiator, supplied by San-Apro Ltd.).
Silane compound: X-12-967C (supplied by Shin-Etsu Chemical Co., Ltd.), acid anhydride silane.

1. A soluble polymer compound containing a structure having a repeating unit represented by chemical formula (1) and further containing a structure derived from an acid anhydride silane residue,
wherein the soluble polymer compound contains a structure represented by chemical formula (2), and in the chemical formula (2), the acid anhydride silane residue is derived from a structure represented by chemical formula (4): 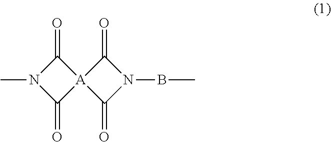
in which A represents a tetravalent tetracarboxylic acid residue having two or more carbon atoms, and B represents a divalent diamine residue having two or more carbon atoms, 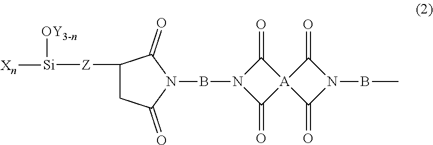
in which A represents a tetravalent tetracarboxylic acid residue having 2 or more carbon atoms, B represents a divalent diamine residue having 2 or more carbon atoms, and n represents an integer of 0 to 3, X represents a structure represented by chemical formula (3), and Y represents a hydrocarbon group having 1 to 10 carbon atoms, and Z represents a silane residue having 1 to 10 carbon atoms, 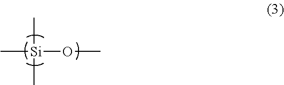
in which an oxygen atom in chemical formula (3) is bonded to a Si atom in chemical formula (2), and

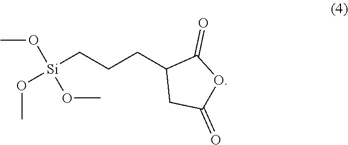 [SMILES: CO[Si](CCCC1CC(=O)OC1=O)(OC)OC]

2. The soluble polymer compound according to claim 1, wherein the tetracarboxylic acid residue of the formula (1) has a structure derived from an alicyclic tetracarboxylic dianhydride.

3. A method for producing the soluble polymer compound (a) according to claim 1, comprising the step of copolymerizing raw materials used in a polymerization process at a condition where the following equation (1) is satisfied when referring a total amount of tetracarboxylic dianhydrides to as A mol, a total amount of diamines to as B mol, and a total amount of acid anhydride silanes to as C mol.
$$0.6 ≦ B / ( A + 0.5 C ) ≦ 0 \text{.98} . \qquad Equation ( 1 )$$

4. A resin composition containing the soluble polymer compound according to claim 1.

5. A negative-type photosensitive resin composition further containing a polymerizable compound and a photopolymerization initiator in the resin composition according to claim 4.

6. The negative-type photosensitive resin composition according to claim 5, wherein the polymerizable compound is a cationic polymerizable compound, and the photopolymerization initiator is a photo cationic polymerization initiator.

7. A resin composition film comprising the resin composition according to claim 4.

8. A cured film obtained by curing the resin composition according to claim 4.

9. An electronic component comprising the cured film according to claim 8.
